(19) United States
(12) Patent Application Publication
(10) Pub. No.: US 2017/0215547 A1
(43) Pub. Date: Aug. 3, 2017

(54) HAIR DRYER

(71) Applicant: Yong Hak LEE, Fullerton, CA (US)

(72) Inventor: Yong Hak LEE, Fullerton, CA (US)

(21) Appl. No.: 15/490,701

(22) Filed: Apr. 18, 2017

Related U.S. Application Data
(63) Continuation of application No. 14/449,988, filed on Aug. 1, 2014.

(30) Foreign Application Priority Data
Aug. 5, 2013 (KR) 10-2013-0092509

(51) Int. Cl. A45D 20/12; H05K 9/00

(52) U.S. Cl. CPC A45D 20/12; H05K 9/0064; H05K 9/0007

(57) ABSTRACT

The present disclosure provides a hair dryer, the hair dryer including a housing, a switch unit, a controller, a fan unit, and a heating unit, wherein the heating unit is configured such that a non-magnetic field is formed by a first heating coil and a second heating coil being twisted in a shape of a twisted bread stick, where the first heating coil is flowed by a current of first direction and the second heating coil is flowed by a current of second direction opposite to the first direction, at least one of the first coil and the second coil is coated with an insulating shield member, and the first coil and the second coil is wound on a support member in a spiral shape.

### CROSS-REFERENCE TO RELATED APPLICATIONS

Pursuant to 35 U.S.C.§119 (a), this application claims the benefit of earlier filing date and right of priority to Korean Patent Application No.10-2013-0092509, filed on Aug. 5, 2013, the contents of which are all hereby incorporated by reference herein in its entirety.

### BACKGROUND OF THE INVENTION

Field of the Invention

The teachings in accordance with the exemplary embodiments of this present disclosure generally relate to a hair dryer having a shielding function against magnetic field and electromagnetic wave.

Description of Related Art

Generally, a hair dryer, which applies an electrical power of a power supplying part to a dryer body, is used to dry a wet hair and/or style a hair by blowing warm or cool air introduced by a blowing fan using an electric wire using an electric resistance.

A hair dryer includes a housing, a blowing fan, a heating unit and a control plate, and the housing includes a handle, an air inlet configured to supply air to the blowing fan and a nozzle unit configured to discharge air heated by the heating unit. At this time, the heating unit may be provided with a nickel-chrome wire or a nickel-iron wire using a heater coil. When an electricity is applied to the heat coil forming a heating unit, an electromagnetic field is generated and an electromagnetic wave formed with electric field and magnetic field directly act on a human body, particularly on a head with fine blood vessels to disturb nerve system whereby living cells such as brain cells may be disadvantageously disrupted or alopecia may be caused.

### SUMMARY OF THE DISCLOSURE

An exemplary embodiment of the present disclosure is to provide a hair dryer configured to improve a structure of a heating unit so that electromagnetic field can be shielded.

In one general aspect of the present disclosure, there is provided a hair dryer, the hair dryer comprising:

a housing including a handle graspable by a user, a suction grille introduceable of air, and a nozzle discharging a heated air;

a switch unit connected at one end to a power unit to open and close a power supply by being interlocked to a user switching operation;

a controller receiving a power by being connected to the switch unit and mounted with an automatic ground circuit configured to ground-process an electromagnetic wave generated during power supply;

a fan unit mounted inside the housing and operated by a driving motor configured to discharge an air to the nozzle by introducing the air through the suction grille; and

a heating unit mounted on a path between the suction grille and the nozzle to heat the air discharged by the fan unit, wherein

the heating unit may be configured such that a non-magnetic field is formed by a first heating coil and a second heating coil being twisted in a shape of a twisted bread stick, where the first heating coil is flowed by a current of first direction and the second heating coil is flowed by a current of second direction opposite to the first direction, at least one of the first coil and the second coil is coated with an insulating shield member, and the first coil and the second coil is wound on a support member in a spiral shape.

Preferably, but not necessarily, the first and second coils twisted in the shape of a twisted bread stick may be formed by being twisted again in a spring shape.

Preferably, but not necessarily, the hair dryer may further comprise an electromagnetic wave shield unit interposed between the housing and the heating unit to shield the heat and electromagnetic wave from the heating unit from being transmitted to the housing and a user.

Preferably, but not necessarily, the electromagnetic wave shield unit may include a plating unit formed by being plated on an inner wall surface of the housing with a conductive material, a first mesh member arranged at a position corresponding to that of a suction grille of the driving motor, a second mesh member arranged at a position corresponding to that of the nozzle, wherein the first and second mesh members are formed by any one of a fish net shape and a plate member having a plurality of through holes.

Preferably, but not necessarily, the electromagnetic wave shield unit may include an electromagnetic wave shield member mounted at a space formed by the heating unit, the fan unit and the housing to wrap a circumference of the heating unit and the fan unit, and an insulation member interposed among the electromagnetic wave shield member, the heating unit and the fan unit.

Preferably, but not necessarily, the electromagnetic wave shield member may be formed by any one material of permalloy and a silicon steel plate.

Preferably, but not necessarily, the electromagnetic wave shield member may form the electromagnetic wave shield unit by rolling a plate-shaped member in any one shape of a cylinder and a cone.

Preferably, but not necessarily, the electromagnetic wave shield member may form the electromagnetic wave shield unit by rolling a plate-shaped member in any one shape of a cylinder and a cone.

Preferably, but not necessarily, the electromagnetic wave shield member may be grounded.

Preferably, but not necessarily, the electromagnetic wave shield member may be formed by rolling a plate-shaped member in any one shape of a cylinder and a cone, and both distal ends of the plate-shaped member may be fixed by any one method of a riveting, a welding and an adhesive fixing.

Preferably, but not necessarily, the electromagnetic wave shield unit may include a plating unit formed by being plated on an inner wall surface of the housing with a conductive material, a first mesh member arranged at a position corresponding to that of a suction grille of the driving motor, a second mesh member arranged at a position corresponding to that of the nozzle, and an electromagnetic wave shield member formed by any one material of permalloy and a silicon steel plate, and mounted at a space formed by the heating unit, the fan unit and the housing to wrap a circumference of the heating unit and the fan unit, wherein the first and second mesh members are formed by any one of a fish net shape and a plate member having a plurality of through holes.

Preferably, but not necessarily, the controller may include a driving motor configured to drive the fan unit, and an automatic ground circuit configured to be connected to the electromagnetic wave shield unit to shield an electromagnetic wave generated during power supply.

In another general aspect of the present disclosure, there is provided a hair dryer, the hair dryer comprising:

a housing including a handle graspable by a user, a suction grille introduceable of air, and a nozzle discharging a heated air;

a switch unit connected at one end to a power unit to open and close a power supply by being interlocked to a user switching operation;

a controller receiving a power by being connected to the switch unit and mounted with an automatic ground circuit configured to ground-process an electromagnetic wave generated during power supply;

a fan unit mounted inside the housing and operated by a driving motor configured to discharge an air to the nozzle by introducing the air through the suction grille;

a heating unit mounted on a path between the suction grille and the nozzle to heat the air discharged by the fan unit;

an electromagnetic wave shield member mounted at a space formed by the heating unit, the fan unit and the housing to wrap a circumference of the heating unit and the fan unit, and formed by any one material of permalloy and a silicon steel plate, wherein the heating unit is configured such that a support member may be alternately wound at a predetermined distance with a first heating coil flowed by a current of a first direction and a second heating coil flowed by a current of a second direction, and

wherein the electromagnetic wave shield unit may include a plating unit formed by being plated on an inner wall surface of the housing with a conductive material, a first mesh member arranged at a position corresponding to that of a suction grille of the driving motor, a second mesh member arranged at a position corresponding to that of the nozzle, and wherein

the first and second mesh members may be formed by any one of a fish net shape and a plate member having a plurality of through holes.

Preferably, but not necessarily, each of the first and second heating coils may be provided in a zigzag shape to increase an area contacted by air.

Preferably, but not necessarily, the first and second heating coils may be provided with a single coil member, wherein the first heating coil may be formed by winding of the second heating coil to a direction opposite to a direction of the first heating coil being wound to a distal end of the support member.

### Advantageous Effects of the Disclosure

The hair dryer according to an exemplary embodiment of the present disclosure has an advantageous effect in that a heating unit can be formed with non-magnetic field, because a heating coil of heating unit is so formed as to offset a magnetic field generated in response to Fleming's left hand rule when an electricity is applied to the heating unit.

Another advantageous effect is that a shield member configured to wrap and ground a heating unit is mounted to shield an electromagnetic wave that may be generated when a heating unit is operated, whereby the electromagnetic wave harmful to human body can be prevented from being transmitted to a user.

Still another advantageous effect is that an electromagnetic wave shield member is formed with a permalloy or a silicon steel plate to wrap a heating unit and a motor part that generate an electromagnetic wave, whereby direct transmission of electromagnetic wave to a user of hair dryer can be minimized.

Still further advantageous effect is that generation and propagation of electromagnetic wave can be doubly shielded if an electromagnetic wave shield member is grounded.

### BRIEF DESCRIPTION OF DRAWINGS

FIG. 1 is a schematic view illustrating a hair dryer according to an exemplary embodiment of the present disclosure.

FIGS. 2 and 3 are schematic views illustrating a heating coil of a heating unit according to a first exemplary embodiment of the present disclosure.

FIGS. 4 and 5 are schematic views illustrating a heating coil of a heating unit according to a second exemplary embodiment of the present disclosure.

FIG. 6 is a schematic view illustrating a heating unit wound with a heating coil according to first and second exemplary embodiments of the present disclosure.

FIGS. 7 and 8 are schematic views illustrating a heating coil of a heating unit according to a third exemplary embodiment of the present disclosure.

FIG. 9 is a schematic view illustrating a hair dryer according to a fourth exemplary embodiment of the present disclosure.

FIGS. 10 and 11 are schematic views illustrating examples of first and second mesh members.

FIGS. 12 to 14 are schematic views illustrating a hair dryer according to a fifth exemplary embodiment of the present disclosure.

### DETAILED DESCRIPTION OF THE DISCLOSURE

A hair dryer according to exemplary embodiments of the present disclosure will be described more fully hereinafter with reference to the accompanying drawings.

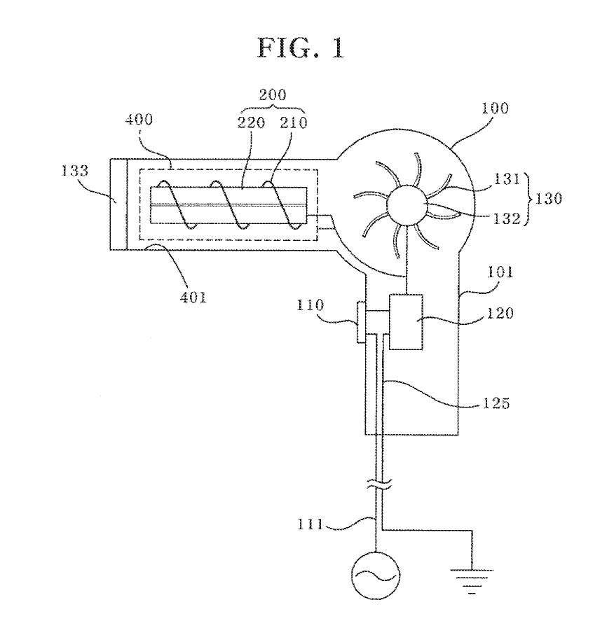

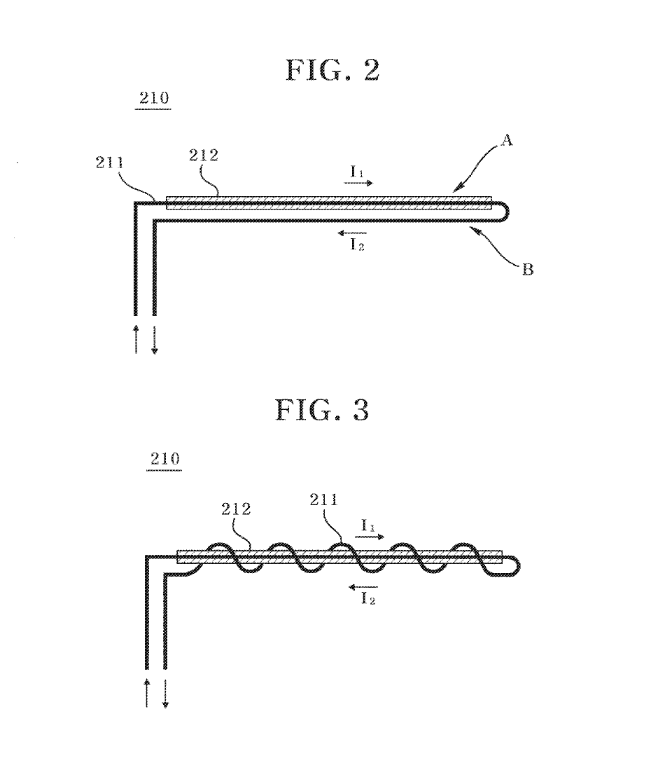

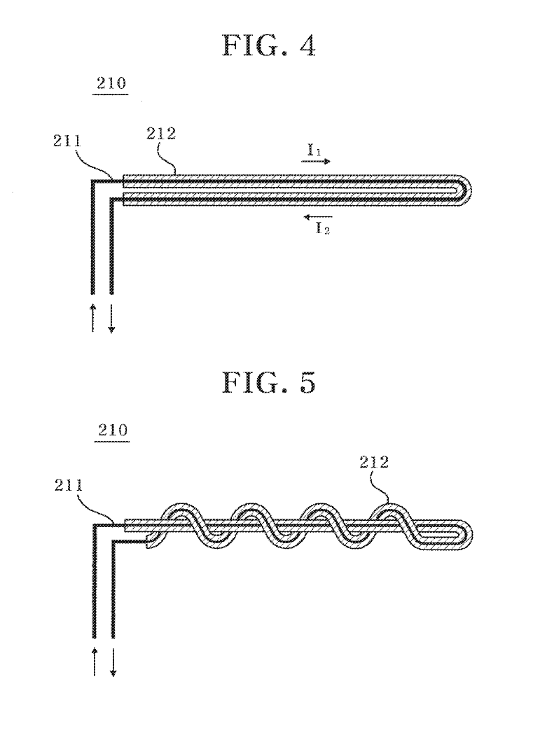

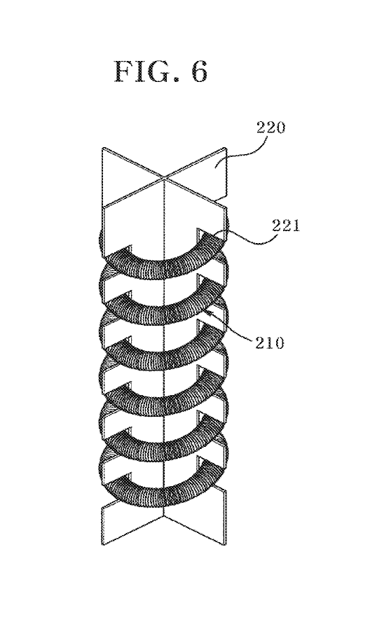

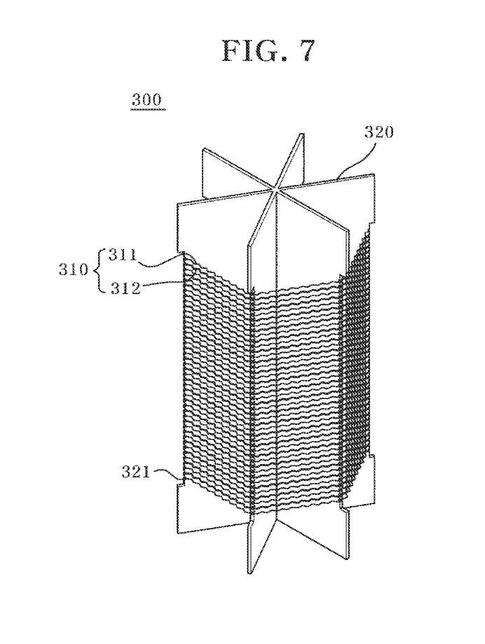

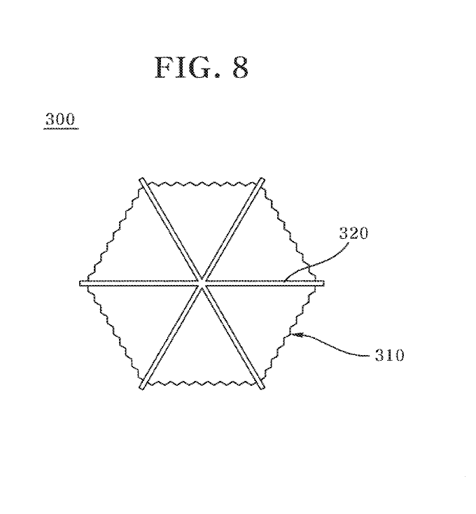

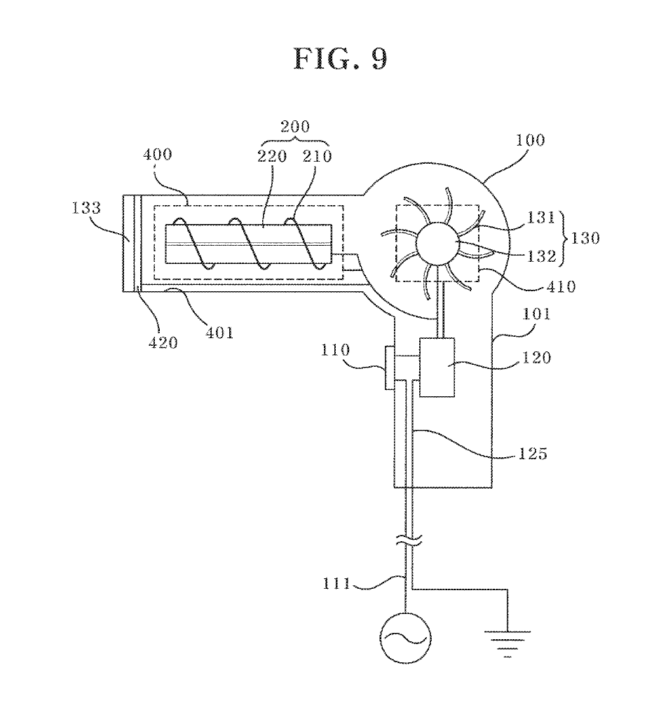

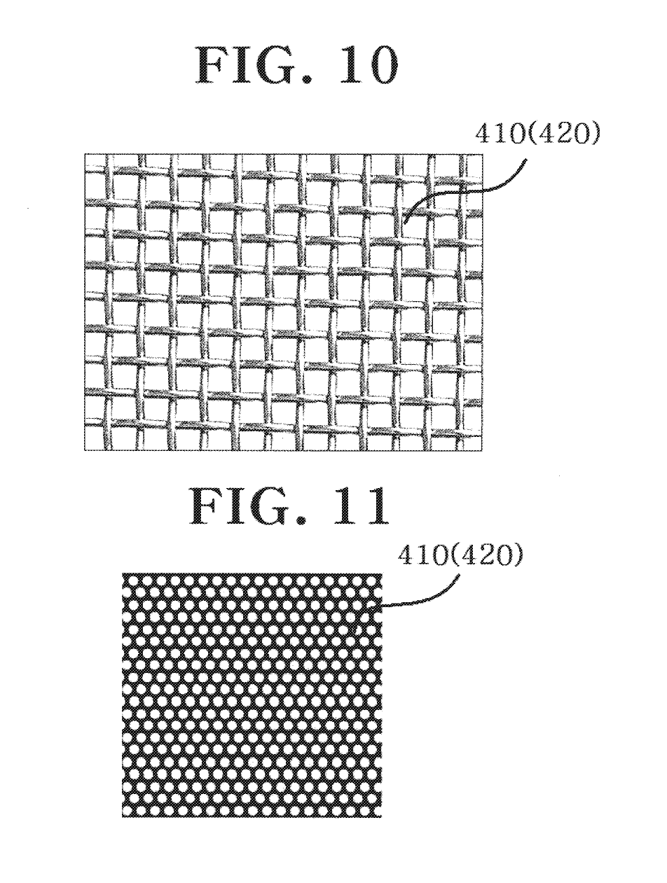

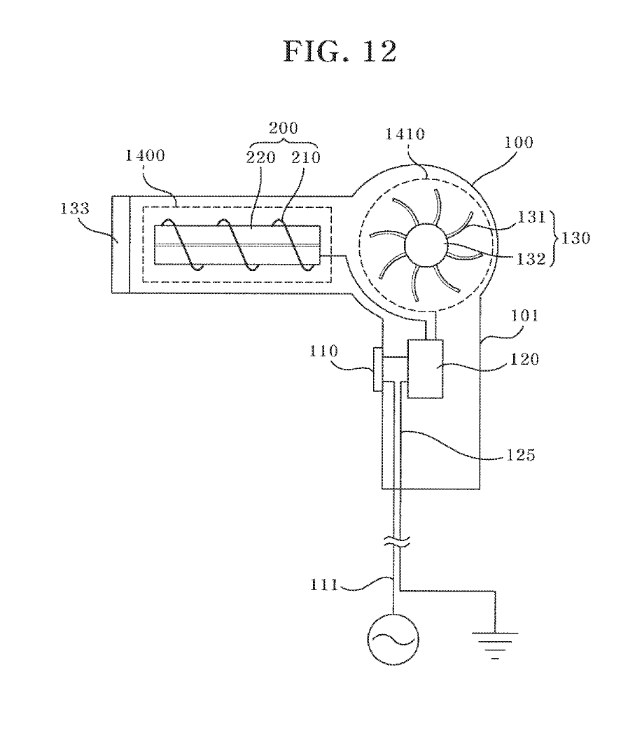

FIG. 1 is a schematic view illustrating a hair dryer according to an exemplary embodiment of the present disclosure, FIGS. 2 and 3 are schematic views illustrating a heating coil of a heating unit according to a first exemplary embodiment of the present disclosure, FIGS. 4 and 5 are schematic views illustrating a heating coil of a heating unit according to a second exemplary embodiment of the present disclosure, FIG. 6 is a schematic view illustrating a heating unit wound with a heating coil according to first and second exemplary embodiments of the present disclosure, FIGS. 7 and 8 are schematic views illustrating a heating coil of a heating unit according to a third exemplary embodiment of the present disclosure, FIG. 9 is a schematic view illustrating a hair dryer according to a fourth exemplary embodiment of the present disclosure, FIGS. 10 and 11 are schematic views illustrating examples of first and second mesh members, and FIGS. 12 to 14 are schematic views illustrating a hair dryer according to a fifth exemplary embodiment of the present disclosure.

As illustrated, the hair dryer according to a first exemplary embodiment of the present disclosure may include, in a housing (100), a switch unit (110), a controller (120), a fan unit (130), a heating unit (200) and an electromagnetic wave shield unit (400).

The housing (100) may be mounted with a handle (101) graspable by a user hand, and may be mounted with a switch unit (110) at a position easily touchable by a finger.

The switch unit (110) may be formed in a change-over type switch configured to physically contact or distance a terminal electrode, or may be formed in a touch type switch of electrostatic/reduced pressure method. The change-over operation of the switch unit (110) allows application to and interruption of electricity to the hair dryer.

The controller (120) may perform a first function of transmitting a power supplied through the switch unit (110) to the fan unit (130), and a second function of conductively connecting a driving motor (not shown) provided at the fan unit (130) to the electromagnetic wave shield unit (400) using an automatic ground circuit and connecting same to a ground terminal connected to a power line (111), or grounding through a separate ground line (125) as illustrated in the drawings.

The fan unit (130) may include a rotation blade (131) having a plurality of wings to discharge air through a nozzle (133) by sucking an outside air through a suction grille (not shown), and a driving motor (132) rotating the rotation blade (131). The shape and structure of the fan unit (130) may be variably formed depending on type and configuration of hair dryer. Meantime, the driving motor (132) may be generally provided in a widely-used electric motor including a stator and a rotor to generate electromagnetic wave during operation of driving motor (132). However, the electromagnetic wave can be removed by grounding using the ground line (125).

The heating unit (200) according to first and second exemplary embodiments of the present disclosure may include a heating coil (210, 211) formed with a material of nickel-chrome wire or a nickel-steel wire configured to generate a heat caused by resistance when a current is applied, a shield member (212) coated on the heating coil (210, 211) and a support member (220), where a first section (A) and a second section (B) are formed in the same length and current direction may be opposite in order to form a non-magnetic field by offset of magnetic field generated when a current passes.

According to the first exemplary embodiment of the present disclosure, an insulation shield member (212) such as heat-resistant coating may be coated on the heating coil (211) in the first section (A), and the heating coil (210, 211) may be exposed as it is in the second section (B).

The reason of forming the first and second sections (A, B) is because the size of heating unit may be excessively increased when the heating coil (210, 211) divided into the first section (A) and the second section (B) are formed by twisting in a twisted bread stick and when both sections (A, B) are provided with the shield member (212). That is, when the second section (B) is formed to expose the heating coil (210, 211) as it is, the second section (B) is thinned as much as the coated thickness to prevent the volume of the heating unit (200) from being excessively increased even if the first and second sections are formed by twisting.

According to the second exemplary embodiment of the present disclosure, the heating coils (210, 211) in both the first and second sections (A, B) may be coated with the insulation shield member (212) such as heat-resistant coating. In this case, although the volume of the heating unit (200) may be slightly increased over the first exemplary embodiment, it may be applied to a relatively voluminous product such as the one used in beauty parlor, where the hair dryer is not greatly subject to the volume (size) of the heating unit (200).

As illustrated in FIGS. 3, 4 and 5, the heating coil (211), provided with the first and second sections (A, B) of same length to form the non-magnetic field as noted above, may be formed in a twisted bread stick. That is, as illustrated in FIGS. 3, 4 and 5, the first section (A) may be formed in a flat shape, on which the heating coil (211) of the second section (B) is formed by rolling. Alternatively, although not illustrated, it is possible to form by rolling and twisting the first and second sections (A, B).

The heating coil (210, 221) thus twisted is twisted once again in a spring shape, as illustrated in FIG. 6, which is in turn rolled in a spiral shape on the support member (220) to form the heating unit (200). When the heating unit (200) is formed by rolling the heating coil (210, 221) in the spiral shape on the support member (220), there is an effect of removing once more the magnetic field that has not yet been removed from the heating coil (210, 221).

Meantime, FIGS. 7 and 8 are schematic views illustrating a heating coil of a heating unit according to a third exemplary embodiment of the present disclosure.

Referring to FIGS. 7 and 8, a heating unit (300) may be formed by alternately rolling a coil member (310) formed with first and second heating coils (311, 312) on a support member (320), where the support member (320) may be formed with pitch grooves (321) with a predetermined size and at a predetermined distance so that the first and second heating coils (311, 312) can be rolled at a predetermined pitch.

The first and second heating coils (311, 312) are so provided as to allow currents to flow in mutually opposite directions. For example, the first heating coil (311) may be rolled clockwise to an upper end of the support member (320) while the second heating coil (312) may be formed by being rolled counterclockwise on a space of the prior-rolled first heating coil (311).

In another example, it may be possible that the first and second heating coils (311, 312) are provided with mutually different heating coil members, alternately arranged in positions thereof, and the heating coils (311, 312) are made to allow currents to flow in mutually different directions. At this time, the first and second heating coils (311, 312) may be alternately rolled on the support member (320) and may be arranged to be spaced apart at a predetermined distance.

According to an exemplary embodiment of the present disclosure, the surfaces of the heating coils (311, 312) may be coated with heat-resistant coating, and may be provided to expose a wire member of the heating coil such as nickel-chrome wire as it is.

Furthermore, the heating coils (311, 312) may be formed in a zigzag shape to allow contacting air on a broader surface, whereby it is possible to maximally form a heating capacity per unit area through this configuration.

Meantime, as illustrated in FIG. 1, the heating units (200, 300) according to the first, second and third exemplary embodiments of the present disclosure may be mounted with an electromagnetic wave shield unit (400) in order to shield additional shield of electromagnetic wave that may be generated at the time of operation. The electromagnetic wave shield unit (400) may be treated at an inner side with an embossed heat insulation member to prevent the heat of the heating units (200, 300) from being transmitted, and at an outer side with an outer shell of metal material, which is then grounded to shield off the generated electromagnetic wave.

The electromagnetic wave shield unit (400) may be provided in various shapes, that is, may be provided in a shape corresponding to that of the housing (100) or may be provided in a cylindrical shape, a square shape or an oval shape. However, an inner space may be formed to encompass all the afore-mentioned heating units (200, 300).

Furthermore, as illustrated in FIG. 1, an inner side of the housing (100) may be formed with a plating unit (401) plated with a conductive material such as chromed and nickel, when the plating unit (401) is connected to an automatic ground circuit provided at the controller (120), the function of shielding the electromagnetic wave can be accomplished.

Furthermore, as illustrated in FIG. 9, in order to further shield the electromagnetic wave that may be additionally generated from the electromagnetic wave shield unit (400), a first mesh member (410) may be mounted at a position corresponding to that of a suction grille (not shown) configured to suck an outside air into the fan unit (130), and a second mesh member (420) may be further mounted at a position corresponding to that of a nozzle (133).

At this time, the first and second mesh members (410, 420) may be formed with a conductive material, and may be connected to an automatic ground circuit mounted at the controller (120) to prevent hazardous electromagnetic wave from being emitted to outside. The first and second mesh members (410, 420) may be formed with a fishnet shape as illustrated in FIG. 9, and may be provided with a plate member of metal material having a plurality of through holes as illustrated in FIG. 10.

Thus, the electromagnetic wave generated from the driving motor (132) in response to operation of the hair dryer can be initially grounded through the automatic ground circuit mounted at the controller (120), and the electromagnetic wave that is not yet prevented may be shielded by the first mesh member (410). The magnetic field and the electromagnetic wave generated from the heating unit (200) may be initially prevented from being generated by way of twisted heating coils for forming the non-magnetic field and may be secondly grounded through the automatic ground circuit mounted at the controller (120), and any electromagnetic wave that is not yet prevented from leaking may be finally shielded by the second mesh member (420).

As illustrated in FIGS. 3, 4 and 5, various wirings for supplying power to an interior of the hair dryer and grounding may be provided in a twisted manner as in the heating unit (200), whereby the electromagnetic wave generated by the current passing through the wirings can be minimized.

FIGS. 12 to 14 are schematic views illustrating a hair dryer according to a fifth exemplary embodiment of the present disclosure.

Basically, the hair dryer according to a fifth exemplary embodiment of the present disclosure has no big difference from the hair dryer according to the first to fourth exemplary embodiments of the present disclosure in terms of configuration.

When compared with the first exemplary embodiment, the fifth exemplary embodiment is different in terms of configuration of an electromagnetic wave shield unit (1400). That is, the electromagnetic wave shield unit (1400) according to the fifth exemplary embodiment of the present disclosure may be so mounted as to encompass a periphery of the heating unit (200) and the fan unit (130). At this time, the electromagnetic wave shield unit (1400) may be mounted at a space formed by the heating unit (200) and the fan unit (130) and the housing (100). The electromagnetic wave shield member (1401) is a plate(d) member formed in any one material of permalloy and a silicon steel plate.

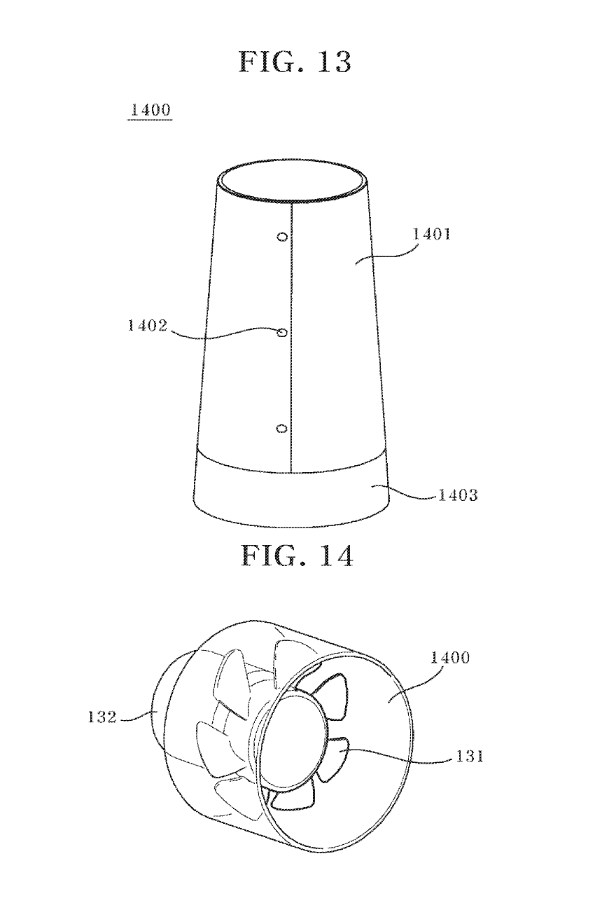

Furthermore, the electromagnetic wave shield member (1401) may be formed by rolling the plate member in a cylindrical shape or a cone shape as illustrated in FIG. 13. At this time, the electromagnetic wave shield unit (1400) may be grounded. Furthermore, both distal ends of the rolled electromagnetic wave shield member (1401) may include a fixture (1402) for fixing the both distal ends using a riveting method, a welding method or an adhesive method. The electromagnetic wave shield unit (1400) may be spaced apart from the heating unit (200) at a predetermine distance, and may be formed by rolling a periphery of a cylindrically provided insulation member (1403), where the material of the insulation member (1403) may be mica, or the insulation member may be formed by injection molding method.

Furthermore, as illustrated in FIG. 14, the electromagnetic wave shield unit (1400) of permalloy and a silicon steel plate may be formed at mounted at a periphery of the fan unit (130). At this time, the configuration of the electromagnetic wave shield unit (1400) may correspond to the wrapping configuration of the heating unit (200).

Although not illustrated, the first to fourth exemplary embodiments and the fifth exemplary embodiment may be simultaneously formed. That is, the first and second mesh members for shielding the electromagnetic wave and the shield member of permalloy material may be simultaneously configured. According to the configuration thus mentioned, the electromagnetic wave shield unit (1400) may initially shield electromagnetic wave by wrapping a periphery of the heating unit (200) and the fan unit (130) that generate the electromagnetic wave, and may secondly shield the electromagnetic wave through the ground line, whereby transmission to a user of the hair dryer of electromagnetic wave can be minimized.

Although the present disclosure has been described in detail with reference to the foregoing embodiments and advantages, many alternatives, modifications, and variations will be apparent to those skilled in the art within the metes and bounds of the claims. Therefore, it should be understood that the above-described embodiments are not limited by any of the details of the foregoing description, unless otherwise specified, but rather should be construed broadly within the scope as defined in the appended claims.

What is claimed is:

1. A hair dryer, the hair dryer comprising:
a housing including a handle graspable by a user, a suction grille for receiving outside air, and a nozzle discharging heated air;
a switch unit connected at one end to a power unit to open and close a power supply by being interlocked to a user switching operation;
a controller receiving a power by being connected to the switch unit and mounted with an automatic ground circuit configured to ground-process an electromagnetic wave generated during power supply;
a fan unit mounted inside the housing and operated by a driving motor configured to discharge the air to the nozzle by introducing the air through the suction grille;
a heating unit mounted on a path between the suction grille and the nozzle to heat the air discharged by the fan unit; and
an electromagnetic wave shield unit mounted at an inner space formed by the heating unit, the fan unit and the housing to wrap a circumference of the heating unit and the fan unit, the electromagnetic wave shield formed by permalloy, wherein the electromagnetic wave shield unit includes a plating unit formed by being plated on an inner wall surface of the housing with a conductive material, a first mesh member arranged at a position corresponding to that of the suction grille of the driving motor, and a second mesh member arranged at a position corresponding to that of the nozzle,
wherein the first and second mesh members are formed by a fish net shape or a plate member having a plurality of through holes,
wherein the heating unit is configured such that a non-magnetic field is formed by a first heating coil and a second heating coil being twisted in a shape of a twisted bread stick, where the first heating coil is flowed by a current of first direction and the second heating coil is flowed by a current of second direction opposite to the first direction, at least one of the first coil and the second coil is coated with an insulating shield member, and the first coil and the second coil is wound on a support member in a spiral shape,
wherein the first and second coils twisted in the shape of a twisted bread stick are formed by being twisted again in a spring shape, and
wherein the electromagnetic wave shield member is formed by rolling a plate-shaped member in any one shape of a cylinder or a cone, and both distal ends of the plate-shaped member are fixed by any one method of a riveting, a welding and an adhesive fixing.

2. The hair dryer of claim 1, wherein each of the first and second heating coils is provided in a zigzag shape to increase an area contacted by air.

3. The hair dryer of claim 1, wherein the first and second heating coils are provided with a single coil member, wherein the first heating coil is formed by winding of the second heating coil to a direction opposite to a direction of the first heating coil being wound to a distal end of the support member.

4. The hair dryer of claim 1, wherein the electromagnetic wave shield member is grounded.
